(19) United States
(12) Patent Application Publication
(10) Pub. No.: US 2025/0275066 A1
(43) Pub. Date: Aug. 28, 2025

(54) DISPLAY PANEL AND MANUFACTURING METHOD THEREOF

(71) Applicant: Wuhan China Star Optoelectronics Semiconductor Display Technology Co., Ltd., Wuhan, Hubei (CN)

(72) Inventors: Jiajie WANG, Wuhan, Hubei (CN); Qiang LU, Wuhan, Hubei (CN); Yingchuan JIANG, Wuhan, Hubei (CN); Wenxu XIANYU, Wuhan, Hubei (CN)

(21) Appl. No.: 18/851,096

(22) PCT Filed: Jun. 30, 2023
(86) PCT No.: PCT/CN2023/104437

§ 371 Date: Sep. 26, 2024

(30) Foreign Application Priority Data
Nov. 18, 2022 (CN) 202211449094.1

(51) Int. Cl. H05K 5/00

(52) U.S. Cl. CPC H05K 5/0069

(57) ABSTRACT

A display panel and a manufacturing method thereof. The display panel includes a display panel body having a plurality of binding terminals disposed on a backlight side of the display panel body; an adhesive layer including a plurality of first through-holes; a chip on film including a chip on film body portion in contact with an adhesive layer, a plurality of connection terminals being provided on a side of the chip on film body portion facing toward the adhesive layer; where a conductive adhesive is disposed in the first through-hole, and the connection terminal is electrically connected to the binding terminal through the conductive adhesive.

### TECHNICAL FIELD

The present disclosure relates to the field of display technology, and more particularly, to a display panel and a manufacturing method thereof.

### BACKGROUND

In recent years, high screen-to-body ratio display technology has become a research hotspot in the field of display technology. Compared with conventional display panels, display panels with a high screen-to-body ratio have a wider display area under the same screen size, which is conducive to enhancing the user experience.

To achieve a high screen-to-body ratio, a back-bonding method is often used to reduce the width of the display panel's bezel. As shown in FIG. 1, the current conventional back-bonding scheme involves setting binding terminals 101′ in the edge area on the backlight side of the display panel body 10′, and sequentially stacking a first support layer 20′, a heat dissipation buffer composite layer (super clean foam, referred to as: SCF) 30′, a double-sided adhesive layer 40′, a second support layer 50′, and a chip on film (referred to as: COF) 60′ in the middle area on the backlight side of the display panel body 10′. Connection terminals 601′ are provided on the edge of the side of the chip on film 60′ that is away from the display panel body 10′, and the binding terminals 101′ are electrically connected to the connection terminals 601′ via conductive adhesive 70′.

However, in this structure, to ensure that the conductive adhesive 70′ may smoothly transition from the edge area to the middle area, it is necessary to provide a first protective adhesive 80′ to support the conductive adhesive 70′. At the same time, to ensure the electrical performance of the conductive adhesive 70′, a second protective adhesive 90′ is additionally required to seal and protect the conductive adhesive 70′, making the manufacturing process more complicated. Moreover, the dispensing of the first protective adhesive 80′ and the second protective adhesive 90′ is challenging, and the dispensing shape and amount are difficult to control, which may easily lead to problems such as glue overflow or insufficient dispensing, resulting in a lower yield in the production of display panels. This issue is in urgent need of resolution.

### SUMMARY

The present disclosure provides a display panel and its manufacturing method, which may effectively solve the problems of complicated manufacturing processes and low yield caused by the setting of protective adhesive in existing display panels.

In one aspect, the present disclosure provides a display panel, the display panel includes: a display panel body provided with a plurality of binding terminals on a backlight side of the display panel body; an adhesive layer disposed on the backlight side of the display panel body, the adhesive layer including a plurality of first through-holes, the first through-holes being provided in correspondence with the binding terminals; a chip on film provided on a side of the adhesive layer facing away from the display panel body and including a chip on film body portion in contact with the adhesive layer, a plurality of connection terminals are provided on a side of the chip on film body portion facing toward the adhesive layer, the connection terminals being provided in correspondence with the first through-holes; where a conductive adhesive is disposed in the first through-hole, and the connection terminal is electrically connected to the binding terminal through the conductive adhesive.

Optionally, the chip on film body portion includes a plurality of second through-holes, the second through-holes being provided in correspondence with the first through-holes, and an opening area of the second through-hole being less than an opening area of the first through-hole.

Optionally, an axis of the first through-hole and an axis of the second through-hole are collinear.

Optionally, the connection terminal is provided around a periphery of the second through-hole, and the conductive adhesive is provided in both the first through-hole and the second through-hole.

Optionally, the display panel further includes: a support layer disposed on a side of the chip on film body portion facing away from the display panel body; a heat dissipation buffer composite layer disposed on a side of the support layer facing away from the display panel body.

Optionally, an orthographic projection of the support layer on the display panel body is a first projection, an orthographic projection of the heat dissipation buffer composite layer on the display panel body is a second projection, and both the first projection and the second projection cover respective ones of the binding terminals.

Optionally, the display panel further includes: a double-sided adhesive layer disposed on a side of the heat dissipation buffer composite layer facing away from the display panel body; where the chip on film further includes a chip on film extension portion, where one end of the chip on film extension portion is connected to the chip on film body portion, and another end of the chip on film extension portion is bent to a side of the double-sided adhesive layer facing away from the display panel body, and is fixedly connected to the double-sided adhesive layer.

Optionally, the display panel further includes: a flexible circuit board provided on a side of the chip on film extension portion facing away from the display panel body and electrically connected to the other end of the chip on film extension portion; an integrated circuit provided on a side of the chip on film extension portion facing away from the display panel body.

Optionally, the display panel further includes: a flexible circuit board provided on a side of the chip on film body portion facing away from the display panel body; an integrated circuit disposed on the side of the chip on film body portion facing away from the display panel body; where the display panel further includes at least one notch penetrating through the support layer and the heat dissipation buffer composite layer, the flexible circuit board and the integrated circuit are located in the notch, and the notch and the binding terminal are arranged in a misalignment manner.

Optionally, the display panel body includes: a first substrate layer disposed on a side of the adhesive layer facing away from the chip on film body portion; a binding terminal layer disposed on a side of the first substrate layer facing away from the chip on film body portion; a barrier layer disposed on a side of the binding terminal layer facing away from the chip on film body portion; a second substrate layer disposed on a side of the barrier layer facing away from the chip on film body portion; where the binding terminal layer includes the plurality of binding terminals, the first substrate layer includes a plurality of third through-holes, the third through-holes being provided in correspondence with the first through-holes, and the conductive adhesive is provided in both the first through-hole and the third through-hole.

In another aspect, the present disclosure provides a method for manufacturing a display panel, the method for manufacturing the display panel includes:
providing a display panel body, where a plurality of binding terminals are provided on a backlight side of the display panel body;
forming an adhesive layer on the backlight side of the display panel body, where the adhesive layer includes a plurality of first through-holes, and the first through-holes are provided in correspondence with the binding terminals;
forming a chip on film on a side of the adhesive layer facing away from the display panel body, where the chip on film includes a chip on film body portion in contact with the adhesive layer, a plurality of connection terminals are provided on a side of the chip on film body portion facing toward the adhesive layer, and the connection terminals are provided in correspondence with the first through-holes;
the method for manufacturing the display panel further includes providing a conductive adhesive in the first through-hole, where the connection terminal is electrically connected to the binding terminal through the conductive adhesive;
where the step of providing the conductive adhesive in the first through-hole precedes or comes after the step of forming the chip on film on the side of the adhesive layer facing away from the display panel body.

### Beneficial Effect

The present disclosure provides a display panel and a manufacturing method thereof. The display panel includes a display panel body provided with a plurality of binding terminals on a backlight side thereof, an adhesive layer including a plurality of first through-holes; a chip on film including a chip on film body portion in contact with an adhesive layer, a plurality of connection terminals being provided on a side of the chip on film body portion facing toward the adhesive layer; where the connection terminals being provided in correspondence with the first through-holes and the binding terminals, and a conductive adhesive being provided in the first through-hole. In the display panel provided in the present disclosure, the first through-hole directly defines the forming position of the conductive adhesive, and the side wall of the first through-hole may well support and protect the conductive adhesive in the first through-hole, so that no additional first protective adhesive or second protective adhesive is required, which avoids the problems of complicated processing and low yield caused by the provision of the protective adhesive, and reduces the manufacturing cost of the display panel.

### BRIEF DESCRIPTION OF THE DRAWINGS

In order that the technical solution in the embodiments of the present disclosure may be explained more clearly, reference will now be made briefly to the accompanying drawings required for the description of the embodiments. It will be apparent that the accompanying drawings in the following description are merely some of the embodiments of the present disclosure, and other drawings may be made to a person of ordinary skill in the art without involving any inventive effort.

FIG. 1 is a schematic diagram of a structure of a display panel in the prior art.

FIG. 2 is a schematic diagram of a structure of a display panel according to Embodiment 1 of the present disclosure.

FIG. 3 is a schematic flow diagram of a method for manufacturing a display panel according to Embodiment 1 of the present disclosure.

FIG. 4 is a schematic diagram of a structure of a display panel according to Embodiment 2 of the present disclosure.

FIG. 5 is a schematic diagram of a structure of a display panel according to Embodiment 3 of the present disclosure.

FIG. 6 is a schematic plan view of a chip on film according to Embodiment 3 of the present disclosure.

FIG. 7 is a schematic flow diagram of a method for manufacturing a display panel according to Embodiment 3 of the present disclosure.

FIG. 8a is a schematic diagram of a structure of a display panel body according to Embodiment 3 of the present disclosure.

FIG. 8b is a schematic view showing a structure in which an adhesive layer is formed on a backlight side of the display panel body according to Embodiment 3 of the present disclosure.

FIG. 8c is a schematic view showing a structure in which a chip on film is formed on a side of an adhesive layer facing away from the display panel body according to Embodiment 3 of the present disclosure.

FIG. 8d is a schematic view showing a structure in which conductive adhesive is provided in a first through-hole according to Embodiment 3 of the present disclosure.

FIG. 8e is a schematic view showing a structure in which a support layer, a heat dissipation buffer composite layer, and a double-sided adhesive layer are sequentially formed on a side of the chip on film body portion facing away from the display panel body according to Embodiment 3 of the present disclosure.

FIG. 8f is a schematic view showing a structure in which an extension portion of the chip on film is folded backward onto a side of the double-sided adhesive layer facing away from the display panel body according to Embodiment 3 of the present disclosure.

FIG. 9 is a schematic diagram of a structure of a display panel according to Embodiment 4 of the present disclosure.

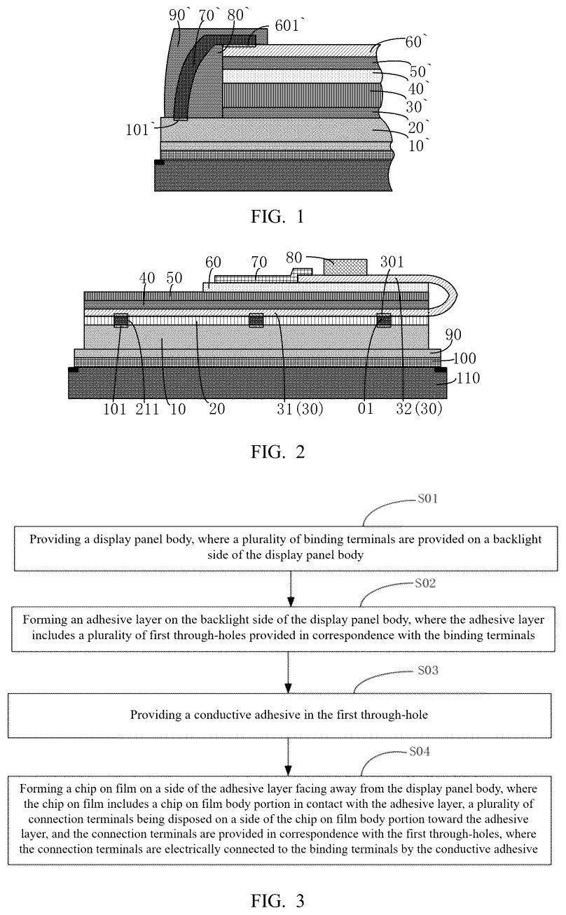

### DETAILED DESCRIPTION

Below, a clear and complete description of the technical solutions in the embodiments of the present disclosure will be provided in conjunction with the drawings of the embodiments, as shown in the present disclosure. Obviously, the described embodiments are only part of the embodiments of the present disclosure, not all of them. All other embodiments obtained by a person of ordinary skill in the art, based on the embodiments in the present disclosure and without the premise of creative labor, fall within the scope of protection of the present disclosure. In addition, it should be understood that the specific implementations described here are only for the purpose of illustrating and explaining the present disclosure and are not intended to limit the present disclosure. In the present disclosure, unless otherwise indicated, directional terms such as “up” and “down” usually refer to the up and down in the actual use or operational status of a device, specifically the direction in the drawings; while “inside” and “outside” refer to the outline of the device.

The following disclosure provides many different implementations or examples to achieve different structures of the present disclosure. To simplify the present disclosure, specific examples of components and settings are described in the following text. Of course, they are merely exemplary and are not intended to limit the present disclosure. Furthermore, the present disclosure may repeat reference numerals and/or letters in different examples; such repetition is for the purpose of simplification and clarity and does not indicate the relationship between the various implementations and/or settings being discussed. In addition, various specific examples of processes and materials are provided in the present disclosure, but a person of ordinary skill in the art may appreciate the application of other processes and the use of other materials. The following will be described in detail, and it should be noted that the order of description of the following embodiments does not limit the preferred order of the embodiments.

### Embodiment 1

FIG. 2 is a schematic diagram of a structure of a display panel according to Embodiment 1 of the present disclosure. Referring to FIG. 2, Embodiment 1 of the present disclosure provides a display panel including a display panel body 10 having a plurality of binding terminals 101 disposed on a backlight side of the display panel body 10; an adhesive layer 20 provided on the backlight side of the display panel body 10, the adhesive layer 20 including a plurality of first through-holes 211 provided in correspondence with the binding terminals 101; a chip on film 30 disposed on a side of the adhesive layer 20 facing away from the display panel body 10, including a chip on film body portion 31 in contact with the adhesive layer 20, a plurality of connection terminals 301 being disposed on a side of the chip on film body portion 31 toward the adhesive layer 20, and the connection terminals 301 being provided in correspondence with the first through-holes 211; where the first through-hole 211 is provided with a conductive adhesive 01, and the connection terminal 301 is electrically connected to the binding terminal 101 through the conductive adhesive 01.

In the display panel provided in the present disclosure, the first through-hole 211 directly defines the forming position of the conductive adhesive 01, and the side wall of the first through-hole 211 can well support and protect the conductive adhesive 01 in the first through-hole 211, so that it is not necessary to additionally provide the protective adhesive having the functions of supporting, sealing, and protecting. Accordingly, the problem that the process is complicated and the yield is low due to the provision of the protective adhesive is also avoided, thereby reducing the manufacturing cost of the display panel.

In addition, in the prior art, the protective adhesive and the conductive adhesive are provided only in the edge region of the backlight side of the display panel body, and therefore, there is a large difference in the design of the film layer structure on the edge region and the middle region of the backlight side of the display panel body. The protective adhesive and the conductive adhesive may deform the display panel body due to shrinkage after curing, thereby affecting the normal display of the display panel. In the display panel provided in the present disclosure, the positions of the first through-hole 211 and the conductive adhesive 01 in the first through-hole 211 are more freely designed, and the first through-hole 211 and the conductive adhesive 01 in the first through-hole 211 may be provided in any area on the backlight side of the display panel body 10 according to actual requirements, so that the design of the film layer structure on the backlight side of the display panel body 10 is more uniform, and the display quality and the use stability of the display panel are improved.

Specifically, orthographic projections of the adhesive layer 20 and the chip on film body portion 31 both cover the display panel body 10, and each of the first through-holes 211 in the adhesive layer 20 is evenly spaced and distributed so that the conductive adhesive 01 located in the first through-holes 211 can be evenly distributed on the area corresponding to the backlight side of the display panel body 10, thereby greatly improving the uniformity of the film layer structure design on the backlight side of the display panel body 10, and improving the display quality and the use stability of the display panel. Accordingly, the connection terminals 301 are evenly spaced and distributed on the area corresponding to the backlight side of the display panel body 10. The binding terminals 101 are evenly spaced and distributed on an area corresponding to the backlight side of the display panel body 10.

In the embodiment of the present disclosure, the display panel further includes a support layer 40 provided on a side of the chip on film body portion 31 facing away from the display panel body 10; a heat dissipation buffer composite layer 50 provided on a side of the support layer 40 facing away from the display panel body 10.

In the prior art, the film layer difference between the binding terminal and the connection terminal is large, the thickness of the conductive adhesive is generally in the range of 200˜400 um, and the extension length of the conductive adhesive in the horizontal direction is generally not less than 500˜1000 um, making it difficult to connect the binding terminal and the binding terminal. In the display panel provided in the present disclosure, because both the support layer 40 and the heat dissipation buffer composite layer 50 are provided on a side of the chip on film body portion 31 facing away from the display panel body 10, the electrical connection between the connection terminal 301 and the binding terminal 101 only needs to pass through the adhesive layer 20, which greatly reduces the process difficulty and the thickness of the conductive adhesive 01 for realizing the electrical connection between the connection terminal 301 and the binding terminal 101, and can reduce the amount of the conductive adhesive 01 used for electrically connecting the connection terminal 301 and the binding terminal 101, thereby saving the process material and reducing the production cost. Meanwhile, because the amount of the conductive adhesive 01 used for electrically connecting the connection terminal 301 and the binding terminal 101 is reduced, deformation during curing of the conductive adhesive 01 may be further reduced or avoided, and display quality and use stability of the display panel may be further improved. Preferably, the conductive adhesive 01 has a thickness of 30 μm or less.

Further, in the embodiment of the present disclosure, the orthographic projection of the support layer 40 on the display panel body 10 is a first projection, the orthographic projection of the heat dissipation buffer composite layer 50 on the display panel body 10 is a second projection, and the first projection and the second projection cover respective ones of the binding terminals 101.

Specifically, in the prior art, because the protective adhesive and the conductive adhesive are provided in the edge region on the backlight side of the display panel body, and the support layer and the heat dissipation buffer composite layer are provided in the middle region on the backlight side of the display panel body, the orthographic projections of the support layer and the heat dissipation composite conductive layer on the display panel body 10 cannot cover the binding terminals 101. Although the protective adhesive has a certain encapsulation and protection effect on the conductive adhesive, the sealing performance is still poor. In the display panel provided in the present disclosure, because the first projection and the second projection cover respective ones of the binding terminals 101, the support layer 40 and the heat dissipation buffer composite layer 50 may cover the binding terminals 101 with multiple film layers, which greatly improves the encapsulation performance of the display panel, and has the beneficial effects of improving the use stability and water-oxygen resistance of the display panel.

Further, the heat dissipation buffer composite layer 50 includes a heat dissipation film formed of a copper foil material, and because the second projection covers respective ones of the binding terminals 101, it is also possible to improve the external interference resistance of the display panel and enhance the shielding performance thereof.

In the embodiment of the present disclosure, the display panel further includes a double-sided adhesive layer 60 disposed on a side of the heat dissipation buffer composite layer 50 facing away from the display panel body 10; where the chip on film 30 further includes a chip on film extension portion 32, one end of which is connected to the chip on film body portion 31, and another end of which is bent to a side of the double-sided adhesive layer 60 facing away from the display panel body 10, and is fixedly connected to the double-sided adhesive layer 60.

In the display panel provided in the present disclosure, the chip on film extension portion 32, which is folded back and fixed to the double-sided adhesive layer 60, may provide space for the arrangement of the flexible circuit board 70 and the integrated circuit 80 without affecting the bonding of the chip on film body portion 31 to the adhesive layer 20.

Specifically, in the embodiment of the present disclosure, the display panel further includes a flexible circuit board 70 provided on a side of the chip on film extension portion 32 facing away from the display panel body 10 and electrically connected to the other end of the chip on film extension portion 32; an integrated circuit 80 provided on a side of the chip on film extension portion 32 facing away from the display panel body 10.

In the embodiment of the present disclosure, the display panel further includes a polarizer 90 provided on a light emitting side of the display panel body 10; an optical adhesive layer 100 disposed on a side of the polarizer 90 facing away from the display panel body 10; a cover plate 110 provided on a side of the optical adhesive layer 100 facing away from the display panel body 10.

In the embodiment of the present disclosure, the type of the display panel includes, but is not limited to, a Liquid Crystal Display (LCD) display panel, an Organic Light-Emitting Diode (OLED) display panel, a Quantum Dot Light-Emitting Diode (QLED) display panel, a mini Light-Emitting Diode (mini LED) display panel, a micro Light-Emitting Diode (micro LED) display panel, and the like.

In another aspect, the present disclosure also provides a method for manufacturing a display panel.

Specifically, FIG. 3 is a schematic flow diagram of a method for manufacturing a display panel according to Embodiment 1 of the present disclosure. As shown in FIGS. 2 and 3, the method for manufacturing the display panel includes the following steps.
S01: Providing a display panel body 10, where a plurality of binding terminals 101 are provided on a backlight side of the display panel body 10.
S02: Forming an adhesive layer 20 on the backlight side of the display panel body 10, where the adhesive layer 20 includes a plurality of first through-holes 211 provided in correspondence with the binding terminals 101.
S03: Providing a conductive adhesive 01 in the first through-hole 211.
S04: Forming a chip on film 30 on a side of the adhesive layer 20 facing away from the display panel body 10, where the chip on film 30 includes a chip on film body portion 31 in contact with the adhesive layer 20, a plurality of connection terminals 301 being disposed on a side of the chip on film body portion 31 toward the adhesive layer 20, and the connection terminals 301 are provided in correspondence with the first through-holes 211, where the connection terminals 301 are electrically connected to the binding terminals 101 by the conductive adhesive 01.

Further, in step S04, the chip on film 30 further includes a chip on film extension portion 32, one end of which is electrically connected to the chip on film body portion 31, the chip on film extension portion 32 protrudes from the display panel body 10, and a flexible circuit board 70 and an integrated circuit 80 are provided on a side of the chip on film extension portion 32 toward the display panel body 10.

Further, the method for manufacturing the display panel further includes the steps.
S05: Sequentially forming a support layer 40, a heat dissipation buffer composite layer 50, and a double-sided adhesive layer 60 on a side of the chip on film body portion 31 facing away from the display panel body 10.
S06: folding the chip on film extension portion 32 back to a side of the double-sided adhesive layer 60 facing away from the display panel body 10, and adhesively fixing the chip on film extension portion 32 and the flexible circuit board 70 to the double-sided adhesive layer 60.

### Embodiment 2

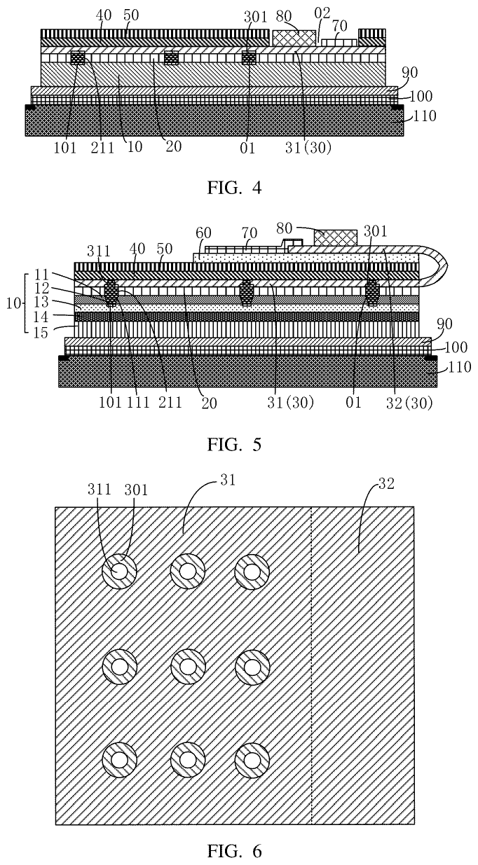

FIG. 4 is a schematic diagram of a structure of a display panel according to Embodiment 2 of the present disclosure. Referring to FIG. 4, Embodiment 2 of the present disclosure provides a display panel including a display panel body 10 having a plurality of binding terminals 101 disposed on a backlight side of the display panel body 10; an adhesive layer 20 provided on the backlight side of the display panel body 10, the adhesive layer 20 including a plurality of first through-holes 211 provided in correspondence with the binding terminals 101; a chip on film 30 disposed on a side of the adhesive layer 20 facing away from the display panel body 10, including a chip on film body portion 31 in contact with the adhesive layer 20, a plurality of connection terminals 301 being disposed on a side of the chip on film body portion 31 toward the adhesive layer 20, and the connection terminals 301 being provided in correspondence with the first through-holes 211; where the first through-hole 211 is provided with a conductive adhesive 01, and the connection terminal 301 is electrically connected to the binding terminal 101 through the conductive adhesive 01.

The display panel provided in Embodiment 2 of the present disclosure is similar in structure to the display panel provided in Embodiment 1 of the present disclosure, and includes a support layer 40 and a heat dissipation buffer composite layer 50. Details of the same parts are not described in this embodiment. In contrast, in the display panel provided in the embodiment of the present disclosure, the chip on film 30 includes only the chip on film body portion 31, that is, the chip on film 30 does not need to be provided with the chip on film extension portion folded back to the side of the heat dissipation buffer composite layer 50 facing away from the display panel body 10, and the chip on film 30 bending process is omitted, thereby reducing process difficulty and saving manufacturing costs.

Specifically, the display panel further includes a flexible circuit board 70 provided on a side of the chip on film body portion 31 facing away from the display panel body 10; an integrated circuit 80 provided on a side of the chip on film body portion 31 facing away from the display panel body 10; where the display panel further includes at least one notch 02 penetrating through the support layer 40 and the heat dissipation buffer composite layer 50, and the flexible circuit board 70 and the integrated circuit 80 are located in the notch 02.

In the display panel provided in the present disclosure, because the flexible circuit board 70 and the integrated circuit 80 are located in the notch 02, the display panel may reduce the overall thickness of the display panel while eliminating the bending process of the chip on film 30, thereby facilitating thinning of the display panel. Further, because the integrated circuit 80 may be electrically connected to respective ones of the connection terminals 301 through the chip on film body portion 31, the connection distance between the integrated circuit 80 and each of the connection terminals 301 may be reduced, thereby reducing the resistance-capacitance delay.

Further, the orthographic projection of the support layer 40 on the display panel body 10 is a first projection, the orthographic projection of the heat dissipation buffer composite layer 50 on the display panel body 10 is a second projection, the first projection and the second projection cover respective ones of the binding terminals 101, and the notch 02 and the binding terminal 101 are arranged in a misalignment manner.

In the display panel provided in the present disclosure, the notch 02 and the binding terminal 101 are arranged in a misalignment manner, so that the support layer 40 and the heat dissipation buffer composite layer 50 may still cover the binding terminal 101 with multiple film layers, thereby greatly improving the encapsulation performance of the display panel, and having the beneficial effects of improving the use stability and the water-oxygen resistance of the display panel.

In another aspect, the present disclosure also provides a method for manufacturing a display panel.

As shown in FIGS. 3 and 4, the method for manufacturing the display panel includes the following steps.

S01: Providing a display panel body 10, where a plurality of binding terminals 101 are provided on a backlight side of the display panel body 10.

S02: Forming an adhesive layer 20 on the backlight side of the display panel body 10, where the adhesive layer 20 includes a plurality of first through-holes 211 provided in correspondence with the binding terminals 101.

S03: Providing a conductive adhesive 01 in the first through-hole 211.

S04: Forming a chip on film 30 on a side of the adhesive layer 20 facing away from the display panel body 10, where the chip on film 30 includes a chip on film body portion 31 in contact with the adhesive layer 20, a plurality of connection terminals 301 being disposed on a side of the chip on film body portion 31 toward the adhesive layer 20, and the connection terminals 301 are provided in correspondence with the first through-holes 211, where the connection terminals 301 are electrically connected to the binding terminals 101 by the conductive adhesive 01.

Further, in the step S04, the chip on film 30 includes only the chip on film body portion 31, and does not include the chip on film extension portion. A flexible circuit board 70 and an integrated circuit 80 are provided on a side of the chip on film body portion 31 facing away from the display panel body 10.

In the embodiment of the present disclosure, the method for manufacturing the display panel includes the following steps.

S05: Sequentially forming a support layer 40, a heat dissipation buffer composite layer 50, and at least one notch 02 penetrating through the support layer 40 and the heat dissipation buffer composite layer 50 on a side of the chip on film body portion 31 facing away from the display panel body portion 10, the orthographic projection of the notch 02 on the chip on film body portion 31 covering orthographic projections of the flexible circuit board 70 and the integrated circuit 80 on the chip on film body portion 31.

Further, in the step S05, the orthographic projection of the support layer 40 on the display panel body 10 is a first projection, the orthographic projection of the heat dissipation buffer composite layer 50 on the display panel body 10 is a second projection, the first projection and the second projection cover respective ones of the binding terminals 101, and the notch 02 and the binding terminal 101 are arranged in a misalignment manner.

### Embodiment 3

FIG. 5 is a schematic diagram of a structure of a display panel according to Embodiment 3 of the present disclosure, and FIG. 6 is a schematic plan view of a chip on film according to Embodiment 3 of the present disclosure. Referring to FIG. 5 and FIG. 6, Embodiment 3 of the present disclosure provides a display panel including a display panel body 10 having a plurality of binding terminals 101 disposed on a backlight side of the display panel body 10; an adhesive layer 20 provided on the backlight side of the display panel body 10, the adhesive layer 20 including a plurality of first through-holes 211 provided in correspondence with the binding terminals 101; a chip on film 30 disposed on a side of the adhesive layer 20 facing away from the display panel body 10, including a chip on film body portion 31 in contact with the adhesive layer 20, a plurality of connection terminals 301 being disposed on a side of the chip on film body portion 31 toward the adhesive layer 20, and the connection terminals 301 being provided in correspondence with the first through-holes 211; where the first through-hole 211 is provided with a conductive adhesive 01, and the connection terminal 301 is electrically connected to the binding terminal 101 through the conductive adhesive 01.

The display panel provided in Embodiment 3 of the present disclosure is similar in structure to the display panel provided in Embodiment 1 of the present disclosure, and includes a support layer 40, a heat dissipation buffer composite layer 50, and a double-sided adhesive layer 60. The chip on film 30 includes a chip on film body portion 31 and a chip on film extension portion 32. Details of the same portions are not described in this embodiment. However, in the display panel provided in the embodiment of the present disclosure, the chip on film body portion 31 includes a plurality of second through-holes 311, the second through-holes 311 are provided in correspondence with the first through-holes 211, and an opening area of the second through-hole 311 is less than an opening area of the first through-hole 211.

Specifically, in the display panel provided in the present disclosure, because the chip on film body portion 31 includes a plurality of second through-holes 311, the second through-holes 311 are provided in correspondence with the first through-holes 211, and the opening area of the second through-hole 311 is less than the opening area of the first through-hole 211, the conductive adhesive 01 may be provided in the first through-holes 211 in such a manner that the conductive adhesive 01 is injected into the second through-holes 311 so that the conductive adhesive 01 flows into the first through-holes 211 in the manufacturing process of the display panel, so that the form of the conductive adhesive 01 in the first through-holes 211 may be more conveniently controlled, and a short circuit problem caused by the conductive adhesive 01 in the first through-holes 211 overflowing the first through-holes 211 is avoided, thereby being more advantageous in cost and efficiency.

Further, an axis of the first through-hole 211 and an axis of the second through-hole 311 are collinear. That is, the line connecting the center point of the first through-hole 211 to the center point of the second through-hole 311 is perpendicular to the plane direction in which the display panel body 10 is located. By collinear the axis of the first through-hole 211 and the axis of the second through-hole 311, the conductive adhesive flowing into the first through-hole 211 through the second through-hole 311 may be more uniformly formed, thereby ensuring the connection effect of the conductive adhesive 01.

Further, the connection terminal 301 is provided around the periphery of the second through-hole 311, and the conductive adhesive 01 is provided in both the first through-hole 211 and the second through-hole 311, so that each area in the first through-hole 211 may be filled with the conductive adhesive 01, thereby ensuring the connection stability of the connecting terminal 301 and the conductive adhesive 01 in the first through-hole 211.

In the embodiment of the present disclosure, the display panel body 10 includes a first substrate layer 11 disposed on a side of the adhesive layer 20 facing away from the chip on film body portion 31; a binding terminal layer 12 disposed on a side of the first substrate layer 11 facing away from the chip on film body portion 31; a barrier layer 13 disposed on a side of the binding terminal layer 12 facing away from the chip on film body portion 31; a second substrate layer 14 disposed on a side of the barrier layer 13 facing away from the chip on film body portion 31; a display functional layer 15 disposed on a side of the second substrate layer 14 facing away from the chip on film body portion 31; where the binding terminal layer 12 includes the plurality of binding terminals 101, the first substrate layer 11 includes a plurality of third through-holes 111, the third through-holes 111 are provided in correspondence with the first through-holes 211, and the conductive adhesive 01 is provided in both the first through-holes 211 and the third through-holes 111.

In comparison with Embodiment 1, the conductive adhesive 01 in the first through-hole 211 needs to pass through the third through-hole 111 in order to be electrically connected to the binding terminal 101, so that the conductive adhesive 01 may be more accurately formed on an area in which the binding terminal 101 is located, thereby further ensuring the electrical connection stability of the conductive adhesive 01 in the first through-hole 211 and the binding terminal 101.

In another aspect, the present disclosure also provides a method for manufacturing a display panel.

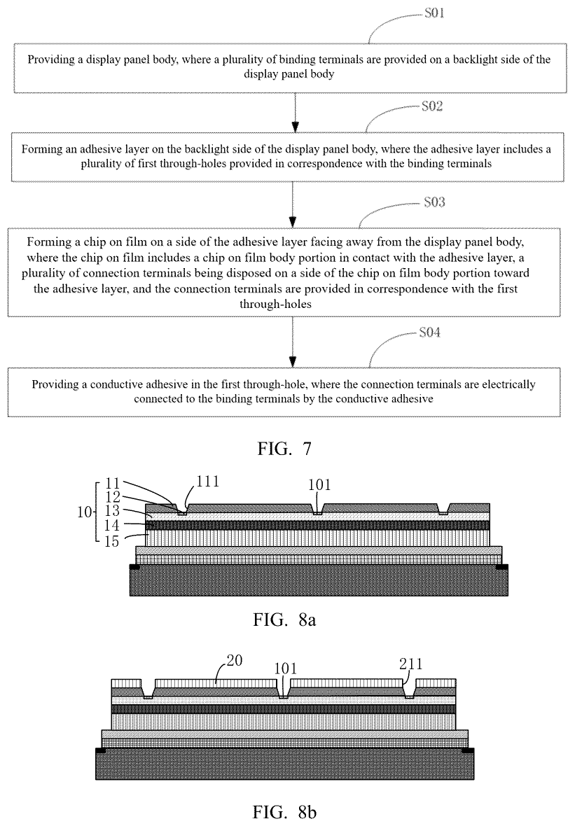

FIG. 7 is a schematic flow diagram of a method for manufacturing a display panel according to Embodiment 3 of the present disclosure. As shown in FIGS. 5 to 7, the method for manufacturing the display panel includes the following steps.

S01: Providing a display panel body 10, where a plurality of binding terminals 101 are provided on a backlight side of the display panel body 10.

S02: Forming an adhesive layer 20 on the backlight side of the display panel body 10, where the adhesive layer 20 includes a plurality of first through-holes 211 provided in correspondence with the binding terminals 101.

S03: Forming a chip on film 30 on a side of the adhesive layer 20 facing away from the display panel body 10, where the chip on film 30 includes a chip on film body portion 31 in contact with the adhesive layer 20, a plurality of connection terminals 301 being disposed on a side of the chip on film body portion 31 toward the adhesive layer 20, and the connection terminals 301 are provided in correspondence with the first through-holes 211.

S04: Providing a conductive adhesive 01 in the first through-hole 211, where the connection terminal 301 is electrically connected to the binding terminal 101 through the conductive adhesive 01.

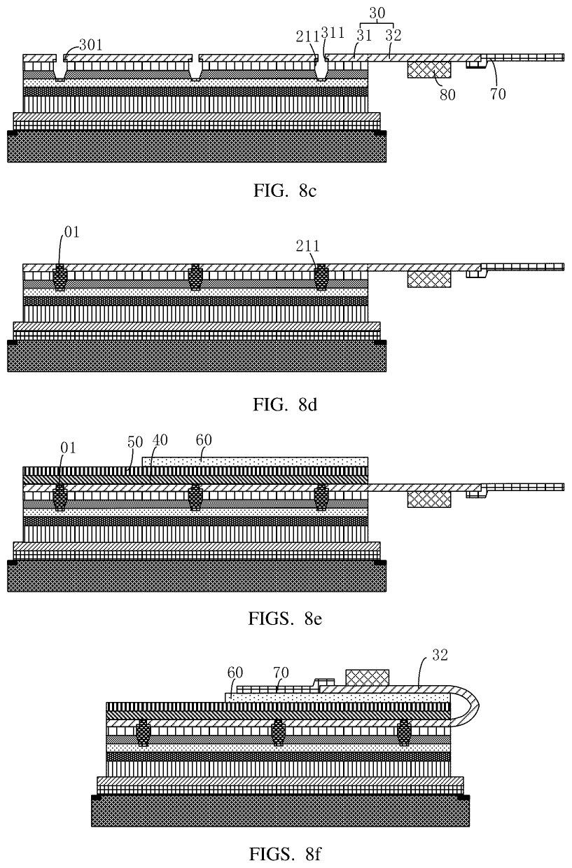

FIG. 8a is a schematic diagram of a structure of a display panel body according to Embodiment 3 of the present disclosure. Referring to FIG. 8a, in the S01 step, the display panel body 10 includes a first substrate layer 11 disposed on a side of the adhesive layer 20 facing away from the chip on film body portion 31; a binding terminal layer 12 disposed on a side of the first substrate layer 11 facing away from the chip on film body portion 31; a barrier layer 13 disposed on a side of the binding terminal layer 12 facing away from the chip on film body portion 31; a second substrate layer 14 disposed on a side of the barrier layer 13 facing away from the chip on film body portion 31; where the binding terminal layer 12 includes the plurality of binding terminals 101, the first substrate layer 11 includes a plurality of third through-holes 111, and the third through-holes 111 are provided in correspondence with the binding terminals 101.

FIG. 8b is a schematic view showing a structure in which an adhesive layer is formed on a backlight side of the display panel body according to Embodiment 3 of the present disclosure. Referring to FIG. 8B, in the step of S02, the first through-holes 211 are provided in correspondence with the third through-holes 111.

FIG. 8c is a schematic view showing a structure in which a chip on film is formed on a side of an adhesive layer facing away from the display panel body according to Embodiment 3 of the present disclosure. Referring to FIG. 8c, in the step of S03, the chip on film body portion 31 includes a plurality of second through-holes 311, which are provided in correspondence with the first through-holes 211, and the opening area of the second through-hole 311 is less than the opening area of the first through-hole 211. The chip on film 30 further includes a chip on film extension portion 32, one end of which is electrically connected to the chip on film body portion 31, the chip on film extension portion 32 protrudes from the display panel body 10, and a flexible circuit board 70 and an integrated circuit 80 are provided on a side of the chip on film extension portion 32 toward the display panel body 10.

FIG. 8d is a schematic view showing a structure in which conductive adhesive is provided in a first through-hole according to Embodiment 3 of the present disclosure. Referring to FIG. 8d, in the step S04, the step of providing conductive adhesive 01 in the first through-hole 211 is completed by injecting conductive adhesive 01 into the second through-hole 311 to flow the conductive adhesive 01 into the first through-hole 211. By providing the conductive adhesive 01 in the first through-hole 211, the form of the conductive adhesive 01 in the first through-hole 211 may be more conveniently controlled, and the problem of short-circuit caused by the conductive adhesive 01 in the first through-hole 211 overflowing the first through-hole 211 is avoided, which has a more advantageous position in terms of cost and efficiency. Further, the conductive adhesive 01 is also provided in the third through-hole 111.

In the embodiment of the present disclosure, the method for manufacturing the display panel further includes steps S05 and S06.

Specifically, FIG. 8e is a schematic view showing a structure in which a support layer, a heat dissipation buffer composite layer, and a double-sided adhesive layer are sequentially formed on a side of the chip on film body portion facing away from the display panel body according to Embodiment 3 of the present disclosure. Referring to FIG. 8e, the S05 step is to sequentially form a support layer 40, a heat dissipation buffer composite layer 50, and a double-sided adhesive layer 60 on a side of the chip on film body portion 31 facing away from the display panel body 10.

Specifically, FIG. 8f is a schematic view showing a structure in which an extension portion of the chip on film is folded backward onto a side of the double-sided adhesive layer facing away from the display panel body according to Embodiment 3 of the present disclosure. Referring to FIG. 8f, the step of S06 is to fold the chip on film extension portion 32 back to a side of the double-sided adhesive layer 60 facing away from the display panel body 10, and adhesively fix the chip on film extension portion 32 and the flexible circuit board 70 to the double-sided adhesive layer 60.

### Embodiment 4

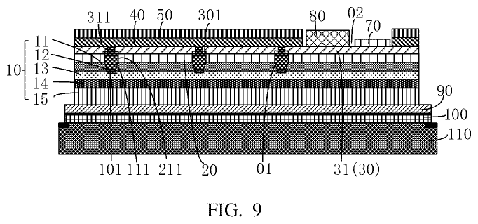

FIG. 9 is a schematic diagram of a structure of a display panel according to Embodiment 4 of the present disclosure. Referring to FIG. 9, Embodiment 4 of the present disclosure provides a display panel including a display panel body 10 having a plurality of binding terminals 101 disposed on a backlight side of the display panel body 10; an adhesive layer 20 provided on the backlight side of the display panel body 10, the adhesive layer 20 including a plurality of first through-holes 211 provided in correspondence with the binding terminals 101; a chip on film 30 disposed on a side of the adhesive layer 20 facing away from the display panel body 10, including a chip on film body portion 31 in contact with the adhesive layer 20, a plurality of connection terminals 301 being disposed on a side of the chip on film body portion 31 toward the adhesive layer 20, and the connection terminals 301 being provided in correspondence with the first through-holes 211; where the first through-hole 211 is provided with a conductive adhesive 01, and the connection terminal 301 is electrically connected to the binding terminal 101 through the conductive adhesive 01.

The structure of the display panel provided in Embodiment 4 of the present disclosure is similar to that of the display panel according to Embodiment 2, and details of the same parts are not described in the present disclosure. However, in the display panel provided in the embodiment of the present disclosure, the chip on film body portion 31 includes a plurality of second through-holes 311, the second through-holes 311 are provided in correspondence with the first through-holes 211, and the opening area of the second through-hole 311 is less than the opening area of the first through-hole 211.

Specifically, in the display panel provided in the present disclosure, because the chip on film body portion 31 includes a plurality of second through-holes 311, the second through-holes 311 are provided in correspondence with the first through-holes 211, and the opening area of the second through-hole 311 is less than the opening area of the first through-hole 211, the conductive adhesive 01 may be provided in the first through-holes 211 in such a manner that the conductive adhesive 01 is injected into the second through-holes 311 so that the conductive adhesive 01 flows into the first through-holes 211 in the manufacturing process of the display panel, so that the form of the conductive adhesive 01 in the first through-holes 211 may be more conveniently controlled, and a short circuit problem caused by the conductive adhesive 01 in the first through-holes 211 overflowing the first through-holes 211 is avoided, thereby being more advantageous in cost and efficiency.

Further, the connection terminal 301 is provided around the periphery of the second through-hole 311, and the conductive adhesive 01 is provided in both the first through-hole 211 and the second through-hole 311, so that each area in the first through-hole 211 may be filled with the conductive adhesive 01, thereby ensuring the connection stability of the connecting terminal 301 and the conductive adhesive 01 in the first through-hole 211.

In the embodiment of the present disclosure, the display panel body 10 includes a first substrate layer 11 disposed on a side of the adhesive layer 20 facing away from the chip on film body portion 31; a binding terminal layer 12 disposed on a side of the first substrate layer 11 facing away from the chip on film body portion 31; a barrier layer 13 disposed on a side of the binding terminal layer 12 facing away from the chip on film body portion 31; a second substrate layer 14 disposed on a side of the barrier layer 13 facing away from the chip on film body portion 31; wherein the binding terminal layer 12 includes the plurality of binding terminals 101, the first substrate layer 11 includes a plurality of third through-holes 111, the third through-holes 111 are provided in correspondence with the first through-holes 211, and the conductive adhesive 01 is provided in both the first through-holes 211 and the third through-holes 111.

In comparison with the second embodiment, the conductive adhesive 01 in the first through-hole 211 needs to pass through the third through-hole 111 in order to be electrically connected to the binding terminal 101, so that the conductive adhesive 01 may be more accurately formed on the area in which the binding terminal 101 is located, thereby further ensuring the electrical connection stability of the conductive adhesive 01 in the first through-hole 211 and the binding terminal 101.

In another aspect, the present disclosure also provides a method for manufacturing a display panel.

As shown in FIGS. 7 and 9, the method for manufacturing the display panel includes the following steps.

S01: Providing a display panel body 10, where a plurality of binding terminals 101 are provided on a backlight side of the display panel body 10.

S02: Forming an adhesive layer 20 on the backlight side of the display panel body 10, where the adhesive layer 20 includes a plurality of first through-holes 211 provided in correspondence with the binding terminals 101.

S03: Forming a chip on film 30 on a side of the adhesive layer 20 facing away from the display panel body 10, where the chip on film 30 includes a chip on film body portion 31 in contact with the adhesive layer 20, a plurality of connection terminals 301 being disposed on a side of the chip on film body portion 31 toward the adhesive layer 20, and the connection terminals 301 are provided in correspondence with the first through-holes 211.

S04: Providing a conductive adhesive 01 in the first through-hole 211, where the connection terminal 301 is electrically connected to the binding terminal 101 through the conductive adhesive 01.

Further, in the step S03, the chip on film body portion 31 includes a plurality of second through-holes 311 provided in correspondence with the first through-holes 211, and an opening area of the second through-hole 311 is less than an opening area of the first through-hole 211. The chip on film 30 includes only a chip on film body portion 31 and does not include a chip on film extension portion 32, where a flexible circuit board 70 and an integrated circuit 80 are provided on a side of the chip on film body portion 31 facing away from the display panel body 10.

In the embodiment of the present disclosure, the method for manufacturing the display panel further includes the steps.

S05: Sequentially forming a support layer 40, a heat dissipation buffer composite layer 50, and at least one notch 02 extending through the support layer 40 and the heat dissipation buffer composite layer 50 on a side of the chip on film body portion 31 facing away from the display panel body portion 10, where an orthographic projection of the notch 02 on the chip on film body portion 31 covers orthographic projections of the flexible circuit board 70 and the integrated circuit 80 on the chip on film body portion 31.

In summary, the present disclosure provides a display panel and a manufacturing method thereof. The display panel includes a display panel body having a plurality of binding terminals disposed on a backlight side of the display panel body; an adhesive layer provided on the backlight side of the display panel body, the adhesive layer including a plurality of first through-holes, the first through-holes being provided in correspondence with the binding terminals; a chip on film provided on a side of the adhesive layer facing away from the display panel body and including a chip on film body portion in contact with the adhesive layer, a plurality of connection terminals being provided on a side of the chip on film body portion facing toward the adhesive layer, the connection terminals being provided in correspondence with the first through-holes; where a conductive adhesive is disposed in the first through-hole, and the connection terminal is electrically connected to the binding terminal through the conductive adhesive. In the display panel provided in the present disclosure, the first through-hole directly defines the forming position of the conductive adhesive, so that the conductive adhesive may be well supported and protected. Therefore, the additional protective adhesive is not required, and the problem that the process is complicated and the yield is low due to the provision of the protective adhesive is avoided.

The above has provided a detailed introduction to a display panel and its manufacturing method provided in the embodiments of the present disclosure. Specific examples have been used in the present disclosure to illustrate the principles and implementation methods of the present disclosure. The descriptions of the embodiments are only for the purpose of aiding in the understanding of the methods and core ideas of the present disclosure. At the same time, for a person of ordinary skill in the art, based on the concepts of the present disclosure, there will be variations in specific implementations and application scopes. In summary, the content of the specification should not be construed as a limitation of the present disclosure.

1. A display panel, wherein the display panel comprises:
a display panel body provided with a plurality of binding terminals on a backlight side of the display panel body;
an adhesive layer disposed on the backlight side of the display panel body, the adhesive layer including a plurality of first through-holes, the first through-holes being provided in correspondence with the binding terminals;
a chip on film provided on a side of the adhesive layer facing away from the display panel body and including a chip on film body portion in contact with the adhesive layer, a plurality of connection terminals are provided on a side of the chip on film body portion facing toward the adhesive layer, the connection terminals being provided in correspondence with the first through-holes;
wherein a conductive adhesive is disposed in the first through-hole, and the connection terminal is electrically connected to the binding terminal through the conductive adhesive.

2. The display panel of claim 1, wherein the chip on film body portion includes a plurality of second through-holes, the second through-holes being provided in correspondence with the first through-holes, and an opening area of the second through-hole being less than an opening area of the first through-hole.

3. The display panel of claim 2, wherein an axis of the first through-hole and an axis of the second through-hole are collinear.

4. The display panel of claim 3, wherein the connection terminal is provided around a periphery of the second through-hole, and the conductive adhesive is provided in both the first through-hole and the second through-hole.

5. The display panel of claim 1, wherein the display panel further
comprises:
a support layer disposed on a side of the chip on film body portion facing away from the display panel body;
a heat dissipation buffer composite layer disposed on a side of the support layer facing away from the display panel body.

6. The display panel of claim 5, wherein an orthographic projection of the support layer on the display panel body is a first projection, an orthographic projection of the heat dissipation buffer composite layer on the display panel body is a second projection, and both the first projection and the second projection cover respective ones of the binding terminals.

7. The display panel of claim 5, wherein the display panel further comprises:
a double-sided adhesive layer disposed on a side of the heat dissipation buffer composite layer facing away from the display panel body;
wherein the chip on film further includes a chip on film extension portion,
wherein one end of the chip on film extension portion is connected to the chip on film body portion, and another end of the chip on film extension portion is bent to a side of the double-sided adhesive layer facing away from the display panel body, and is fixedly connected to the double-sided adhesive layer.

8. The display panel of claim 7, wherein the display panel further comprises:
a flexible circuit board provided on a side of the chip on film extension portion facing away from the display panel body and electrically connected to the other end of the chip on film extension portion;
an integrated circuit provided on a side of the chip on film extension portion facing away from the display panel body.

9. The display panel of claim 6, wherein the display panel further comprises:
a flexible circuit board provided on a side of the chip on film body portion facing away from the display panel body;
an integrated circuit disposed on the side of the chip on film body portion facing away from the display panel body;
wherein the display panel further comprises at least one notch penetrating through the support layer and the heat dissipation buffer composite layer, the flexible circuit board and the integrated circuit are located in the notch, and the notch and the binding terminal are arranged in a misalignment manner.

10. The display panel of claim 1, wherein the display panel body includes:
a first substrate layer disposed on a side of the adhesive layer facing away from the chip on film body portion;
a binding terminal layer disposed on a side of the first substrate layer facing away from the chip on film body portion;
a barrier layer disposed on a side of the binding terminal layer facing away from the chip on film body portion;
a second substrate layer disposed on a side of the barrier layer facing away from the chip on film body portion;
wherein the binding terminal layer includes the plurality of binding terminals, the first substrate layer comprises a plurality of third through-holes, the third through-holes being provided in correspondence with the first through-holes, and
the conductive adhesive is provided in both the first through-hole and the third through-hole.

11. The display panel of claim 10, wherein the chip on film body portion includes a plurality of second through-holes, the second through-holes being provided in correspondence with the first through-holes, and an opening area of the second through-hole being less than an opening area of the first through-hole.

12. The display panel of claim 11, wherein an axis of the first through-hole and an axis of the second through-hole are collinear.

13. The display panel of claim 12, wherein the connection terminal is provided around a periphery of the second through-hole, and the conductive adhesive is provided in both the first through-hole and the second through-hole.

14. The display panel of claim 10, wherein the display panel further comprises:
a support layer disposed on a side of the chip on film body portion facing away from the display panel body;
a heat dissipation buffer composite layer disposed on a side of the support layer facing away from the display panel body.

15. The display panel of claim 14, wherein an orthographic projection of the support layer on the display panel body is a first projection, an orthographic projection of the heat dissipation buffer composite layer on the display panel body is a second projection, and both the first projection and the second projection cover respective ones of the binding terminals.

16. The display panel of claim 14, wherein the display panel further comprises:
a double-sided adhesive layer disposed on a side of the heat dissipation buffer composite layer facing away from the display panel body;
wherein the chip on film further comprises a chip on film extension portion, one end of the chip on film extension portion is connected to the chip on film body portion, and another end of the chip on film extension portion is bent to a side of the double-sided adhesive layer facing away from the display panel body, and is fixedly connected to the double-sided adhesive layer.

17. The display panel of claim 16, wherein the display panel further comprises:
a flexible circuit board provided on a side of the chip on film extension portion facing away from the display panel body and electrically connected to the other end of the chip on film extension portion;
an integrated circuit provided on a side of the chip on film extension portion facing away from the display panel body.

18. The display panel of claim 15, wherein the display panel further comprises:
a flexible circuit board provided on a side of the chip on film body portion facing away from the display panel body;
an integrated circuit disposed on the side of the chip on film body portion facing away from the display panel body;
wherein the display panel further comprises at least one notch penetrating through the support layer and the heat dissipation buffer composite layer, the flexible circuit board and the integrated circuit are located in the notch, and the notch and the binding terminal are arranged in a misalignment manner.

19. The display panel of claim 1, wherein orthographic projections of the adhesive layer and the chip on film body portion both cover the display panel body, and each of the first through-holes in the adhesive layer is evenly spaced and distributed so that the conductive adhesive located in the first through-holes is evenly distributed on the area corresponding to the backlight side of the display panel body,
wherein the connection terminals are evenly spaced and distributed on the area corresponding to the backlight side of the display panel body, and the binding terminals are evenly spaced and distributed on the area corresponding to the backlight side of the display panel body.

20. A method for manufacturing a display panel, wherein the method for manufacturing the display panel comprises:
providing a display panel body, wherein a plurality of binding terminals are provided on a backlight side of the display panel body;
forming an adhesive layer on the backlight side of the display panel body, wherein the adhesive layer includes a plurality of first through-holes, and the first through-holes are provided in correspondence with the binding terminals;
forming a chip on film on a side of the adhesive layer facing away from the display panel body, wherein the chip on film includes a chip on film body portion in contact with the adhesive layer, a plurality of connection terminals are provided on a side of the chip on film body portion facing toward the adhesive layer, and the connection terminals are provided in correspondence with the first through-holes;
the method for manufacturing the display panel further comprises providing a conductive adhesive in the first through-hole, wherein the connection terminal is electrically connected to the binding terminal through the conductive adhesive;
wherein the step of providing the conductive adhesive in the first through-hole precedes or comes after the step of forming the chip on film on the side of the adhesive layer facing away from the display panel body.
